(19) United States
(12) Patent Application Publication
(10) Pub. No.: US 2024/0319135 A1
(43) Pub. Date: Sep. 26, 2024

(54) METHODS OF FABRICATING A MULTIANALYTE DETECTION DEVICE AND DEVICES THEREOF

(71) Applicant: THE TRUSTEES OF BOSTON COLLEGE, Chestnut Hill, MA (US)

(72) Inventors: Kenneth S. Burch, Newton Centre, MA (US); Narendra Kumar, Brighton, MA (US); Michael Geiwitz, West Boylston, MA (US); Matthew Catalano, Huntington, NY (US)

(73) Assignee: The Trustees of Boston College, Chestnut Hill, MA (US)

(21) Appl. No.: 18/575,477

(22) PCT Filed: Jun. 28, 2022
(86) PCT No.: PCT/US22/73201

§ 371 Date: Dec. 29, 2023

Related U.S. Application Data
(60) Provisional application No. 63/216,039, filed on Jun. 29, 2021.

(51) Int. Cl. G01N 27/414; H01L 21/02; H01L 21/027; H01L 21/311; H01L 29/16; H01L 29/66

(52) U.S. Cl. CPC G01N 27/4146; H01L 21/0206; H01L 21/0274; H01L 21/31116; H01L 29/1606; H01L 29/66045

(57) ABSTRACT

A method for fabricating a multianalyte detection device. The multianalyte detection device includes a substrate having a plurality of graphene field effect transistor devices each having a source, a drain, and a side gate located thereon. A graphene layer deposited on the substrate to form a plurality of graphene active regions between the source electrode and the drain electrode of each of the plurality of graphene field effect transistors for detection of an analyte therein. A plurality of graphene windows are located on the graphene active regions for receiving a liquid for detecting of the analyte therein. One or more passivation layers are positioned on the substrate to protect the source electrode and the drain electrode for each of the plurality of graphene field effect transistor devices from the liquid received in the plurality of graphene windows.

### CROSS REFERENCE

This application claims the priority benefit of U.S. Provisional Patent Application Ser. No. 63/216,039, filed Jun. 29, 2021, which is hereby incorporated by reference in its entirety.

This invention was made with government support under Grant No. DMR2003343 awarded by the National Science Foundation and Grant No. N00014-12-1-2308 awarded by the United States Navy. The government has certain rights in the invention.

### FIELD

The present invention relates to methods for fabricating a multianalyte detection device and devices thereof.

### BACKGROUND

Graphene Field Effect Transistor (G-FET) based biosensors have become more prevalent because of their high sensitivity, biocompatibility, non-covalent functionalization, and scalable fabrication over various substrates. Recently, G-FET based biosensors have also been used for the detection of spike protein and RNA of Covid-19 in nasal swab and saliva samples.

The electrical resistance of graphene is highly sensitive to the target bio-analytes (or the probes conformal changes), enabling direct and rapid readout, while the Dirac-point (peak in resistance at charge neutrality) is measured by a gate, providing a quantitative detection of the target concentration. Since graphene has a minimum in its density of states at the Dirac point, by sweeping an external gate the charge on the sheet is revealed by the voltage (V_{D}) at which the resistance is maximized. Upon exposure to a target that charges the graphene, a shift in V_{D} will occur. As such, the sensitivity of G-FET's can be limited by their mobility (reduction in the resistance peak height) and Debye screening (reduction in the induced charge on the channel). In the latter case, large probes are particularly detrimental as they keep the target farther from the channel, dramatically reducing the induced charge.

Graphene is also attractive given its ease of functionalization with an array of pyrene-based linker molecules to immobilize a variety of biological/chemical probes and ability to be implemented on a wide variety of substrates. This has enabled the development of highly sensitive G-FET based sensors for the detection of biomarkers such as CA-I (oral diseases) in saliva. Furthermore, these pyrene-based linkers can be pre-attached to probes (peptides, aptamers) during their synthesis facilitating single step functionalization which enables a highly sensitive GFET biosensor for selective detection of antibiotic resistant bacteria at single cell level.

Traditional back-gated FETs offer reference electrode free devices but require substantial voltages (>60V) with special electronics, and also require drying out the sensor surface for measurement, which can cause denaturation of several bio-analytes of interest. Liquid gated GFET sensors employ a side gate directly incorporated onto the chip that requires much lower voltage range of 0-2 V and keeps the biomolecules active in their original conformation. This approach requires fewer complex electronics than other FET approaches. However, the major challenge with these devices has been keeping their surfaces clean, stability, reproducible fabrication, and their capability for multianalyte detection in a single chip. Most reported research has focused on the detection of single analyte per chip and using an external reference electrode, which limits the capability of miniaturization and multiplexed detection.

The present invention is directed to overcoming these and other deficiencies in the art.

### SUMMARY

One aspect of the present disclosure relates to a method for fabricating a multianalyte detection device. The method includes transferring a graphene layer onto a substrate having sources, drains, and side gates for a plurality of graphene field effect transistor devices located thereon. The graphene layer is baked to improve attachment and clean a surface of the graphene layer. A first passivation layer is deposited on the graphene layer to protect the graphene layer. A second photoresist provided on the first passivation layer is patterned to expose first portions of the graphene layer to be removed from the substrate and to provide second portions of the graphene layer covered by the first passivation layer and the second photoresist layer. The graphene layer is etched to remove the first portions of the graphene layer, wherein the second portions of the graphene layer form a plurality of graphene active regions between the source and the drain electrode of each of the plurality of graphene field effect transistors for detection of an analyte therein. The side gates for the plurality of graphene field effect transistor devices are cleaned. A second passivation layer is deposited on the substrate. A third photoresist layer provided on the second passivation layer is patterned to expose portions of the first passivation layer and the second passivation layer. The portions of the first and second passivation layers are etched to expose graphene windows for the graphene active regions of the graphene layer configured to receive a liquid for detection of the analyte therein, contact pads, and the plurality of graphene field effect transistor devices to form the multianalyte detection device.

Another aspect of the present disclosure relates to a multianalyte detection device. The multianalyte detection device includes a substrate having a plurality of graphene field effect transistor devices each having a source, a drain, and a side gate located thereon. A plurality of graphene windows located on the substrate between the source electrode and the drain electrode of each of the plurality of graphene field effect transistors for receiving a liquid for detection of an analyte therein. One or more passivation layers are positioned on the substrate to protect the source electrode and the drain electrode for each of the plurality of graphene field effect transistor devices from the liquid received in the plurality of graphene windows.

The method so the present disclosure advantageously provides a clean fabrication process that provides a cost effective, reproducible, stable, multiplexed GFET detection platform that, in one example, include a 1.2 cm×1.2 cm chip each having 4 sets of devices. The fabrication process primarily utilizes a single e-beam deposition system used to deposit metals, oxides, baking, and plasma all at one place which makes the process much simpler and cost effective. The fabrication process significantly reduces the cost of production and fabrication time. The present disclosure also provides GFET devices having a coplanar Pt side gate electrode. On chip fabrication of the coplanar Pt side gate provides a miniaturized GFET platform by eliminating the need for external reference electrode with simplified characterization. This constriction allows the upscaling of number of devices and wells on the same chip while measuring them simultaneously. The device further includes passivation with an Al₂O₃ layer, exposing only the active area of graphene and the on-chip electrical gate to the biological targets.

### BRIEF DESCRIPTION OF THE DRAWINGS

FIG. 1 is a flowchart of an exemplary method for fabricating a multianalyte detection device in accordance with the present disclosure.

FIG. 2 is an image of an exemplary multianalyte detection device of the present disclosure located in a chip carrier on a PCB with an attached polydimethylsiloxane (PDMS) well.

FIG. 3 illustrates a layout of the electrode pattern for an exemplary multianalyte detection device having a plurality of graphene field effect transistor (GFET) devices of the present disclosure.

FIG. 4 illustrates a portion of the electrode layout illustrated in FIG. 3.

FIG. 5 is a microscopic image of a portion of an exemplary multianalyte detection device of the present disclosure.

FIG. 6 is a schematic of one of the GFET devices of the multianalyte detection device of the present disclosure.

FIGS. 7A and 7B illustrate resistance versus voltage data for a multianalyte detection device of the present disclosure having 20 separate GFET devices located thereon.

FIG. 8 is a schematic illustration of an onsite chip-based rapid detection platform for near real-time monitoring of opioid metabolites in wastewater using AptG-FET sensor technology.

FIG. 9A is a schematic of a fabricated G-FET; FIG. 9B is a microscopic image of single G-FET with source/drain and side gate electrode, graphene sensing window with AlOx passivation; FIG. 9C illustrates G-FET characteristics upon functionalization with aptamer probes and detection of Noroxycodone; FIG. 9D illustrates concentration dependence of Dirac voltage shift along with shift from high concentration of negative control (EDDP). Error bars were calculated with the data from 3-5 devices at each concentration.

FIG. 10A illustrates a G-FET chip ((1.2 cm×1.2 cm) with 4 PDMS wells; FIG. 10B illustrates a calibration curve for NX in wastewater diluted 20× in PBS with negative control of EDDP and NF, K_{D} value of 490 pM and LOD of 126 pM; FIG. 10C is a calibration curve for EDDP with negative controls of NX and NF, K_{D} value of 115 pM and LOD of 96 pM; FIG. 10D is a calibration curve for NF with negative controls of NX and EDDP, K_{D} value of 60 pM and LOD of 183 pM. Error bars were calculated with the data from 5 devices at each concentration.

FIG. 11A illustrates selective detection of NX from mixed samples with EDDP and NF; FIG. 11B illustrates selective detection of EDDP from mixed samples with NX and NF; and FIG. 11C illustrates elective detection of NF from mixed samples with NX and EDDP.

FIGS. 12A-12C illustrate test results using the multianalyte detection device of the present disclosure to detect the spike protein, HA protein (from influenza A), and the protein on the surface of the Respiratory syncytial viruses (RSV).

### DETAILED DESCRIPTION

The present disclosure relates to methods for fabricating a multianalyte detection device and devices thereof

One aspect of the present disclosure relates to a method for fabricating a multianalyte detection device. The method includes transferring a graphene layer onto a substrate having sources, drains, and side gates for a plurality of graphene field effect transistor devices located thereon. The graphene layer is baked to improve attachment and clean a surface of the graphene layer. A first passivation layer is deposited on the graphene layer to protect the graphene layer. A second photoresist provided on the first passivation layer is patterned to expose first portions of the graphene layer to be removed from the substrate and to provide second portions of the graphene layer covered by the first passivation layer and the second photoresist layer. The graphene layer is etched to remove the first portions of the graphene layer, wherein the second portions of the graphene layer form a plurality of graphene active regions between the source and the drain electrode of each of the plurality of graphene field effect transistors for detection of an analyte therein. The side gates for the plurality of graphene field effect transistor devices are cleaned. A second passivation layer is deposited on the substrate. A third photoresist layer provided on the second passivation layer is patterned to expose portions of the first passivation layer and the second passivation layer. The portions of the first and second passivation layers are etched to expose graphene windows for the graphene active regions of the graphene layer configured to receive a liquid for detection of the analyte therein, contact pads, and the plurality of graphene field effect transistor devices to form the multianalyte detection device.

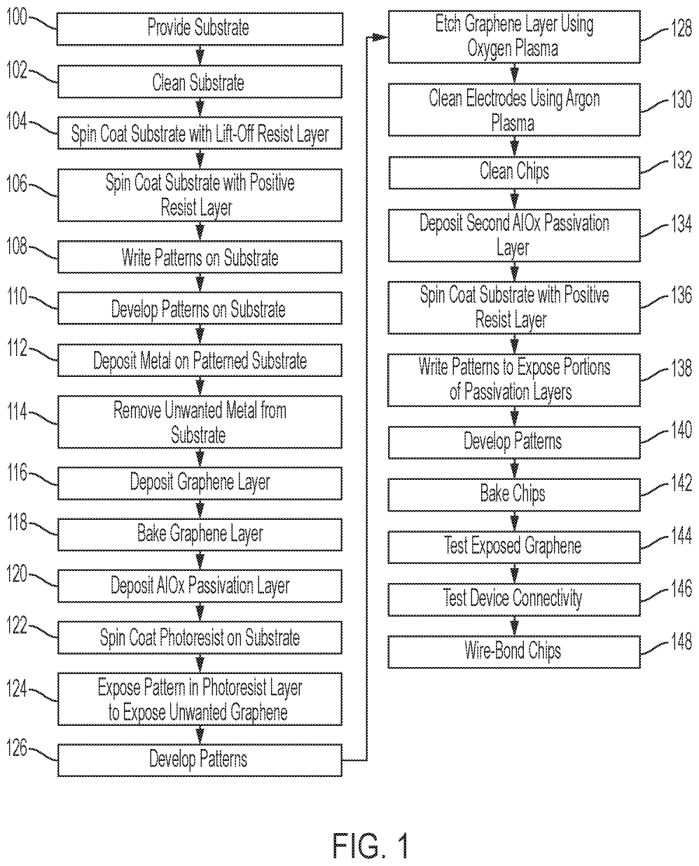

FIG. 1 is a flowchart of an exemplary method for fabricating a multianalyte detection device in accordance with the present disclosure. The fabrication method can be performed in a cleanroom in a glove box as disclosed in Gray, et al., “A Cleanroom in a Glovebox.” Review of Scientific Instruments, 91 (7) (2020), the disclosure of which is incorporated by reference herein in its entirety. The method advantageously reduces the cost of product and fabrication time. Further, the method produces a multianalyte detection device that is configured to provide multiplexed detection of one or more chemicals or bio-analytes, as described in further detail below.

Referring again to FIG. 1, in step 100 a substrate is provided for the multianalyte detection device. The substrate in one example is formed from diced silicon (Si)/silicon dioxide (SiO₂) wafers. In one example, the wafers are diced to approximately 1.2 cm×1.2 cm to provide the dimensions of the substrate. In step 102 the diced wafers or chips that provide the substrate for the multianalyte detection device are cleaned by sonicating in acetone 99%. Isopropyl alcohol (IPA) 99% is then used to clean the acetone followed by deionized water. The chips are then dried with argon and baked at 115 degrees Celsius to dehydrate the chips.

Next, in step 104 the diced chips are spin coated with a lift-off resist, such as LOR1A. The diced chips are baked, for example, on a hotplate for 5 minutes at 175 degrees Celsius to harden the lift-off resist layer. In step 106, the diced chips are spin coated with a positive resist, such as S1805. The diced chips are then baked, for example, on a hotplate for 1 minute at 105 degrees Celsius to harden the positive resist layer.

In step 108, source, drain, and side-gate electrode patterns for a plurality of graphene field effect transistor (GFET) devices are formed on in the photoresist layers deposited on the diced chips. In one example, up to 20 GFET devices are formed on a single chip. In this example, the patterns are exposed using direct write photolithography processes. Next, in step 110, the patterns exposed in step 108, which provide the source, drain, and side-gate electrode patterns, are developed using a developer, such as MF321 developer. Developing the patterns exposes the Si/SiO₂ substrate of the chips below written pattern forming the source, drain, and side-gate electrode patterns. The developer is then cleaned with distilled water and the chips are dried with argon.

In step 112, metal is deposited in the patterns developed on the substrate to form the source, drain, and side-gate electrodes for the plurality of GFETs on the substrate. The metal deposited in this example includes titanium (5 nm) and platinum (20 nm). The metal is deposited using e-beam deposition under vacuum pressure of ˜2×10-6 Torr using an e-beam system, such as the e-beam system developed by Angstrom Engineering (Kitchener, Canada). The electrode size is, for example, 10.2 mm×10 mm. In this manner, the side gates are formed coplanar to the GFET devices on the substrate.

Next, in step 114, metal lift off is performed in Remover PG to remove deposited metals in unwanted areas. The chips are then cleaned with IPA and de-ionized water. The chips are then dried with argon. In step 116, a graphene layer is deposited on the substrate. Prior to depositing the graphene, copper etched with FeCL₃ from CVD graphene is coated with polydimethylsiloxane (PDMS) to protect the graphene during copper etching and transfer. The graphene is cleaned in two baths of de-ionized water and then transferred directly from water baths to the substrate. The deposited graphene layer is slowly dried with argon and then baked, for example, on a hotplate at 115 degrees Celsius to further dry. The PDMS is removed from top of graphene using acetone. The chips are then cleaned with Remover PG, IPA, and de-ionized water in succession.

In step 118, the chips are put in the e-beam tool, such as the e-beam system developed by Angstrom Engineering (Kitchener, Canada), and baked, for example, at 300 degrees Celsius for 9 hours, to clean a surface of the graphene layer and ensure graphene adhesion to the substrate. The chips are then allowed to slowly cool to room temperature.

In step 120, an aluminum oxide (AlOx) layer is deposited over the graphene layer to protect the graphene. In one example, the AlOx passivation layer has a thickness of about at least 50 nm. The AlOx layer is deposited using an e-beam system, such as the e-beam system developed by Angstrom Engineering (Kitchener, Canada). After depositing the AlOx passivation layer, the chips then removed from the e-beam system and baked, for example, on a hotplate at 175 degrees Celsius for 5 minutes to harden the AlOx passivation layer.

Next, photolithography is used once again to form the desired patterns for the graphene layer. In step 122, the chips are spin coated with a lift-off resist, such as LOR1A and a positive resist, such as S1805, using the same processes described in steps 104 and 106 set forth above. In step 124, photolithography is used to write a pattern in the deposited photoresist layers. The written pattern exposes first portions of the graphene layer that are areas of unwanted graphene to be removed from the substrate as described in further detail below. The written pattern leaves second portions of the graphene layer that are to remain on the substrate covered by the AlOx passivation layer and the deposited photoresist layers. In step 126, the developed patterns in the photoresist layers are developed using the same process as described in step 110 above.

Next, the chips are advantageously etched and cleaned using oxygen and argon plasma, respectively. In step 128, the chips placed in an e-beam tool, such as the e-beam system developed by Angstrom Engineering (Kitchener, Canada), and chamber vacuumed to ˜2×10-6 Torr. Oxygen is then flowed into chamber of the e-beam tool for five minutes to purge. Oxygen plasma is then generated at 75 W for 30 seconds to etch the exposed graphene. Etching the graphene layer removes the first portions of the graphene layer that are exposed during the photolithography process in steps 124 and 126. The second portions of the graphene layer that remain on the substrate form graphene active regions between the source and drain electrodes of each of the plurality of GFETs formed on the substrate. The graphene active regions may be employed for detection of an analyte therein as described in further detail below.

In step 130, the chamber of the e-beam tool is allowed to return to a pressure of ˜2×10−6 Torr for ten minutes to ensure oxygen is removed. Argon is then flowed into the chamber for five minutes to purge. Argon plasma is then generated at 100 W for three minutes. This step advantageously cleans the side gates for the plurality of GFETs formed on the substrate by cleaning the platinum oxide layer formed on the deposited electrodes during the oxygen plasma etching in step 128.

In step 132, the chips are removed from the chamber of the e-beam tool and cleaned for deposition of second passivation layer. Remaining resists from the deposited photoresist layers deposited in step 122 are removed with Remover PG, IPA, and de-ionized water. Any remaining unwanted AlOx from the deposition of the first passivation layer in step 120 is removed with MF321 developer and cleaned with de-ionized water.

Next, in step 134, the chips returned to the e-beam tool, such as the e-beam system developed by Angstrom Engineering (Kitchener, Canada), for deposition of a second passivation layer. In this example, AlOx is deposited for the second passivation layer having a thickness of at least about 50 nm. During deposition of the second passivation layer, oxygen is flowed into the chamber of the e-beam tool to maintain a pressure of approximately 10-5 Torr. This ensures high quality AlOx is deposited as the e-beam process can strip oxygen from the AlOx making it more metallic. The second AlOx passivation layer serves as passivation preventing electrical bleed through from the electrodes as well as protecting the electrodes from chemicals used during functionalization. The chips are then baked, for example, on a hotplate at 175 degrees Celsius for five minutes after deposition to harden the second AlOx passivation layer.

In step 136 the chips are spin coated with a positive resist, such as S1805, using the same process described above in step 106. In step 138 photolithography used to write a pattern in the photoresist layer deposited in step 136 to expose contact pads for wire bonding to the electrodes as well as the graphene device areas or windows, as described in further detail below. This exposes portions of the first and second AlOx passivation layers below the written pattern. In step 140, the written pattern is developed using the process described above in step 110.

In step 142, the chips are baked at 120 degrees Celsius on a hotplate for five minutes to harden S1805 deposited in step 136, which may have softened during the developing in step 140. This step ensures cleanly etched AlOx passivation layers in the following step. In step 146, the AlOx passivation layers etched from the exposed areas developed in step 140. The etching is performed in this example using diluted Transetch (2 Transetch:1 de-ionized water) heated to 80 degrees Celsius for 7.5 minutes. The etching of the passivation layers in the exposed areas exposes the contact pads, graphene windows in the graphene active regions, and the GFET devices to form the multianalyte detection device, as described in further detail below. The graphene windows are configured to receive a liquid for detection of an analyte therein. In one example, the graphene windows have dimensions of about 10 μm×40 μm. Any remaining resists are removed using Remover PG, IPA, and de-ionized water.

In step 144, the chips may be tested using Raman spectroscopy on the exposed graphene to ensure cleanliness and removal of the AlOx passivation materials therefrom. In step 146, connectivity of the multianalyte detection device is tested using a multimeter. In step 148, chips are then wire-bonded to chip carriers and PDMS wells placed to separate the four sets of GFET devices formed on the chip, as described in further detail below.

Another aspect of the present disclosure relates to a multianalyte detection device. The multianalyte detection device includes a substrate having a plurality of graphene field effect transistor devices each having a source, a drain, and a side gate located thereon. A plurality of graphene windows located on the substrate between the source electrode and the drain electrode of each of the plurality of graphene field effect transistors for receiving a liquid for detection of an analyte therein. One or more passivation layers are positioned on the substrate to protect the source electrode and the drain electrode for each of the plurality of graphene field effect transistor devices from the liquid received in the plurality of graphene windows.

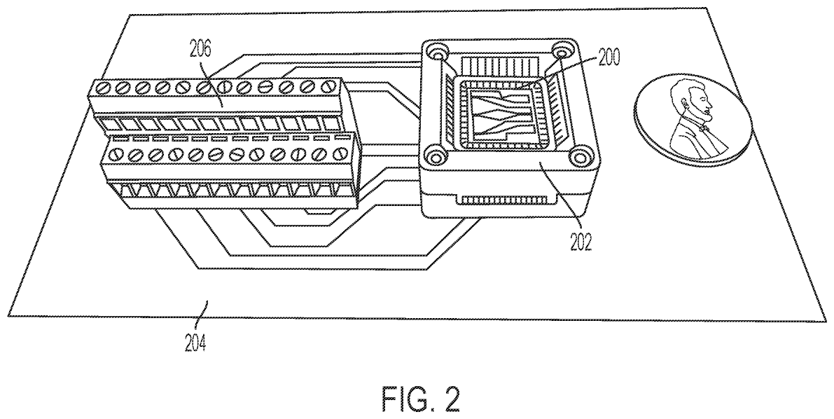

FIG. 2 illustrates an exemplary multianalyte detection device 200 of the present disclosure located in a chip carrier 202 on a printed circuit board 204 with an attached polydimethylsiloxane (PDMS) well 206 (the penny is illustrated to demonstrate size of multianalyte detection device 200. Multianalyte detection device 200 is formed using the methods disclosed herein. Multianalyte detection device 200 provides a cost effective, reproducible, stable, multiplexed GFET detection platform. Multianalyte detection device 200 is configured to provide multiplexed detection of one or more chemicals or bio-analytes. Multiplexed detection device 200 may be used to detect any known chemicals or bio-analytes in the art of GFET-based detection devices.

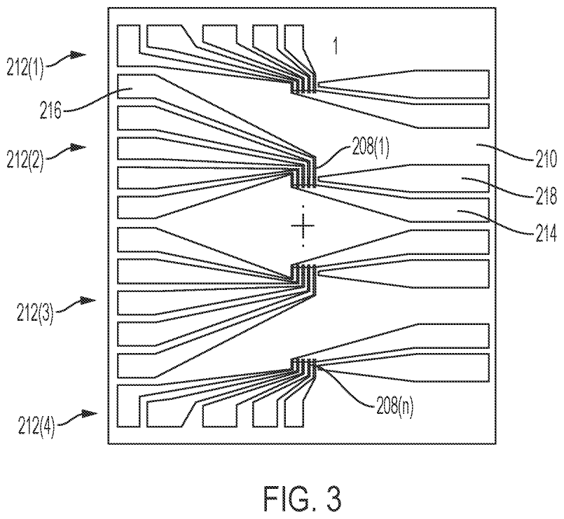

Referring now to FIGS. 3-5, an exemplary electrode layout pattern for multianalyte detection device 200 is illustrated. Multianalyte detection device includes a plurality of GFET devices 208(1)-208(n) located on a substrate 210. GFET devices 208(1)-208(n) are wire bonded to PDMS wells 206, as shown in FIG. 2. PDMS wells 206 separates the active areas on multianalyte detection device 200 allowing each well to be functionalized for a different target and tested separately. This configuration advantageously allows for multiplexed detection of different test targets on the same chip.

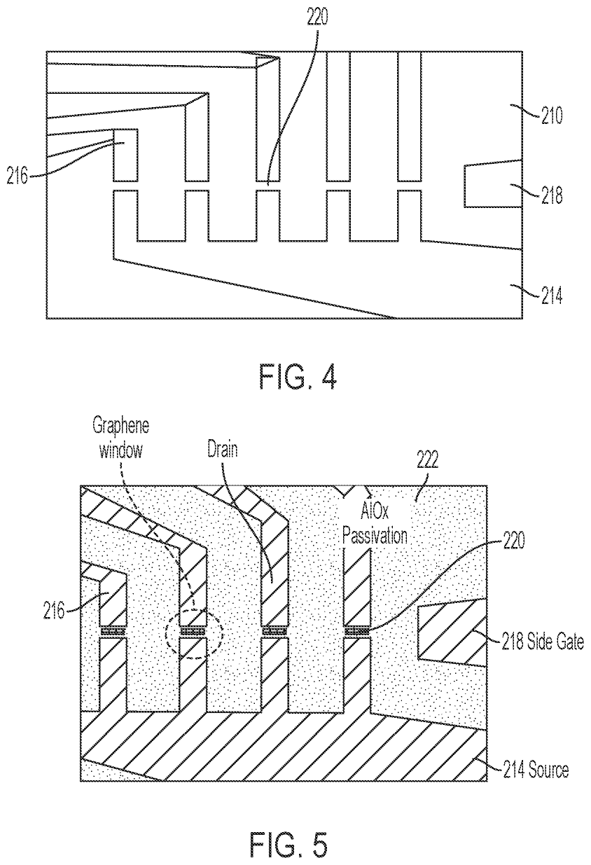

Referring again to FIGS. 3-5, in one example, GFET devices are formed from platinum and titanium, although other suitable materials may be employed. In this example, multianalyte device 200 includes at least twenty GFET devices arranged in four sets 212(1)-212(4) of five GFET devices, although other arrangements and number of GFET devices are contemplated. In one example, substrate 210 is a 1.2 cm×1.2 cm chip formed of diced silicon (Si)/silicon dioxide (SiO₂) wafers. FIGS. 4 and 5 illustrate sections of multianalyte detection device 200 illustrating additional details regarding set 212(2) of GFET devices shown in FIG. 3.

The structure of GFET devices 208(1)-208(n) will now be described with respect to set 212(2) of GFET devices shown in FIGS. 3-5. Although set 212(2) is described, it is to be understood that the other sets of GFET devices are substantially similar in structure and operation. Each of the GFET devices 208(1)-208(n) include a source 214, a drain 216, and a side gate 218 located on the substrate 210. In one example Each of the GFET devices in the set 212(2) share source 214, which provides a ground terminal for the graphene channel resistance measurements. Each of the GFET devices in the set 212(2) have an individual drain 216 electrode that provides a terminal to measure the resistance. This configuration allows each of the GFETs to be operated individually or together as desired. Side gate 218 supplies a gate voltage to the GFET devices when performing resistance measurements. In this example, side gate 218 is co-planar to the GFET devices 208(1)-208(n) on substrate 210. On chip fabrication of the coplanar side gate provides a miniaturized GFET platform by eliminating the need for external reference electrode with simplified characterization. In one example, side gate 218 is formed from platinum, although other suitable materials may be employed.

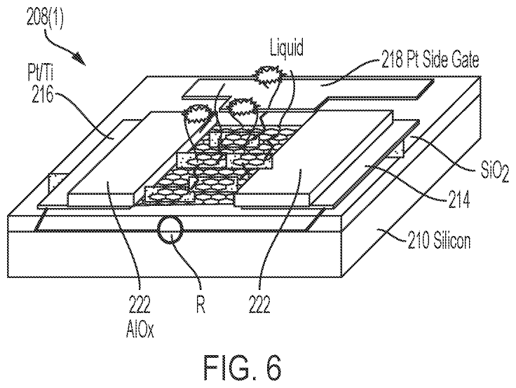

Referring now more specifically to FIGS. 5 and 6, multianalyte detection device 200 also includes a plurality of graphene windows 220 formed on substrate 210 and located between source 214 and drain 216 of each of GFET devices 208(1)-208(n). Graphene windows 220 are configured to receive a liquid therein for detection of an analyte in the liquid using the corresponding GFET device. Graphene windows 220 form active areas functionalized with probes for target detection. Graphene windows 220 are formed in accordance with the method described above. In one example, graphene windows 220 have dimensions of about 10 μm×40 μm.

Multianalyte detection device 200 also includes one or more passivation layers 222 located on substrate 210. Passivation layers 222, in this example, are formed of AlOx and have a thickness of at least 50 nanometers, although other suitable materials and thicknesses may be employed. Passivation layers 222 are formed in accordance with the method described above and serve to protect source 214 and drain 216 electrodes for each of GFET devices 208(1)-208(n) from liquid received in graphene windows 220 for analyte detection. Passivation layers 222 passivate the electrodes to minimize the leakage current and nonspecific absorption outside of graphene windows 220.

The operation of GFET devices 208(1)-208(n) is well known in the art. Multianalyte detection device 200 advantageously provides multiplexed detection of one or more chemicals or bio-analytes. Multiplexed detection device 200 may be used to detect any known chemicals or bio-analytes in the art of GFET-based detection devices.

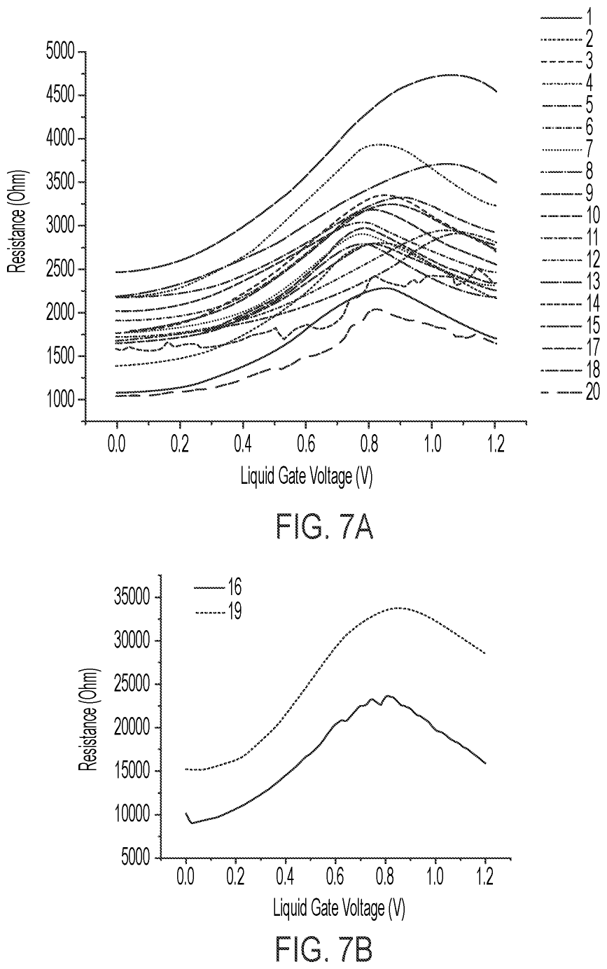

FIGS. 7A and 7B illustrate resistance versus voltage data for a multianalyte detection device of the present disclosure having 20 separate GFET devices located thereon. The voltage was swept from zero to determine the Dirac (charge neutral) point of each of the GFET devices. Side gate voltage was swept from 0 Volts to 1.2 Volts. The peaks shown in FIGS. 7A and 7B represent the Dirac point for each of the devices. FIG. 7A illustrates the Dirac point for 18 of the 20 devices, while FIG. 7B illustrates the Dirac point for the remaining two devices. The figures show 100% working devices with 90% of the devices having a comparable range of resistance values.

The disclosed multianalyte detection device 200 can be employed, for example, in handheld, portable sensors that may be utilized in point-of-care, at-home, or in the field applications. Multianalyte detection device 200 has the ability to provide multiplexed detection of various chemicals and bio-analytes in different mediums (e.g., buffer solutions, clinical samples, saliva, blood, waste water, etc.) known in the art.

### EXAMPLES

The examples below are intended to exemplify the practice of embodiments of the disclosure but are by no means intended to limit the scope thereof.

### Example 1—Rapid, Multianalyte Detection of Opioid Metabolites in Wastewater

By monitoring opioid metabolites, wastewater-based epidemiology (WBE) could be an excellent tool for real-time information on consumption of illicit drugs. A key limitation of WBE is the reliance on costly laboratory-based techniques that require substantial infrastructure and trained personnel, resulting in long turnaround times. Here, an aptamer-based graphene field effect transistor (AptG-FET) platform is presented for simultaneous detection of three different opioid metabolites. This platform provides a reliable, rapid, and inexpensive method for quantitative analysis of opioid metabolites in wastewater (WW). The platform delivers a limit of detection (LOD) 2-3 orders of magnitude lower than previous reports, but in line with the concentrations range (pg/ml to ng/ml) of these opioid metabolites present in real samples. To enable multianalyte detection a facile, reproducible, and high yield fabrication process was developed producing twenty G-FETs with integrated side gate platinum (Pt) electrodes on a single chip. The devices achieved the selective multianalyte detection of three different metabolites: Noroxycodone (NX), 2-ethylidene-1,5-dimethyl-3,3-diphenylpyrrolidine (EDDP), and Norfentanyl (NF) in wastewater diluted 20× in buffer.

Effective responses to the opioid epidemic require real-time and local information on the type and usage frequency of illicit drugs. A recent approach has emerged that avoids many of the difficulties associated with individual testing, namely wastewater-based epidemiology (WBE). This strategy enables community tracing of drug metabolites and tracking the spread of infectious diseases. Wastewater monitoring can provide near real-time feedback on the introduction and continued usage of psychoactive substances without stigmatizing communities, households, or individuals. However, successful WBE requires a highly sensitive and specific detection technique as the concentrations of metabolites in wastewater are very low (pg/ml to ng/ml) due to excessive dilution.

The current gold standard method to detect these drug metabolites is high-pressure liquid chromatography tandem mass spectrometry (HPLC-MS) which requires advanced equipment, sample analyses, skilled personnel, and cannot be performed on site. As such, the implementation of HPLC-MS has been limited by a long turnaround time and cost. Therefore, to make WBE more meaningful and reliable, a rapid, highly sensitive, cost effective, and easy to use detection method is required for on-site analysis of drug metabolites.

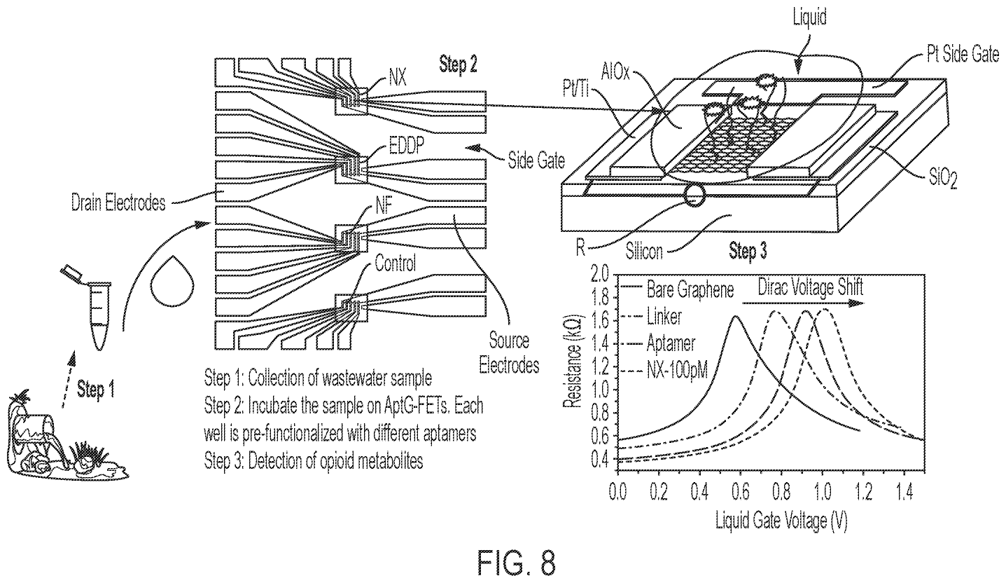

Attempts to achieve these aims have employed different techniques such as colorimetric, fluorescence, surface-enhanced Raman spectroscopy (SERS), lateral flow immunoassay (LFIA), and electrochemical detection. In these approaches, optical detection using nanomaterials-based aptasensors have been extensively investigated for rapid analysis of illicit drugs. Nanomaterials are utilized to achieve high sensitivity and lower limit of detection (LOD) values while aptamer probes possess excellent affinity, stability at room temperature, smaller size, and can be chemically synthesized on a large scale and at low-cost. For example, a gold nanoparticles conjugated assay was reported with a LOD of 0.5 nM (0.15 ng/ml) and 3.3 nM (1 ng/ml) for methamphetamine and Cocaine respectively. The optical assays-based techniques using nanomaterials are limited by high LOD, miniaturization, complex equipment, and cost. On the other hand, the LFIA and electrochemical sensors have the capability to solve several challenges, but have yet to achieve high sensitivity and stability in real wastewater samples. For instance, a nafion-coated carbon nanotube electrode can specifically detect Oxycodone with a LOD of 85 nM (27 ng/ml), which is quite high considering the very low amount (˜pg/ml) for several drug metabolites present in wastewater samples. Similarly, an LFIA based sensor showed sensitivity (LOD) values of 5-50 ng/ml for detecting Fentanyl (Norfentanyl as metabolite) but were only tested with urine, PBS, and saliva samples and not in wastewater. The LFIA still suffers from low sensitivity and quantification while the electrochemical sensors require complex fabrication due to dependence on nanomaterial modification to achieve the desired detection limit. Moreover, most experimental approaches such as enzyme-linked immunosorbent assay (ELISA) and LFIA mostly rely on antibodies that might be incompatible with waster while suffering from inconsistencies between vendors and product lots. Graphene field effect transistors (G-FETs) with aptamer probes have not yet been implemented into a field deployable wastewater sensor. Referring to FIG. 8, a miniaturized G-FET platform utilizing highly specific aptamers (AptG-FET) was developed for rapid, sensitive, and simultaneous detection of drug metabolites in wastewater. The process involves: Step 1, wastewater collection, filtration, and dilution (as needed); Step 2, on chip sample (10 μL) incubation; Step 3, sensor characterization of the sensor to estimate the concentration of targeted drug metabolites.

G-FET based biosensors have emerged as sensors with a large potential due to their high sensitivity, biocompatibility, non-covalent functionalization, and scalable fabrication on various substrates. The electrical resistance of graphene is highly sensitive to the target bio-analytes (or the conformal changes of the probe), enabling direct and rapid readout. A highly sensitive G-FET for the detection of biomarkers such as CA-I (oral diseases biomarker) in saliva, and antibiotic resistant bacteria, both at clinically relevant concentrations was previously developed. However, the G-FET design was limited to detection of a single target, with each chip functionalized with a single probe, provided minimal passivation, and required a platinum (Pt) wire as a separate reference electrode.

Thus, the previous G-FETs were not appropriate for WBE, where one requires multi-analyte detection and robust devices on a self-contained chip. To achieve this, a facile and reproducible fabrication process for multiple, isolated sets of G-FETs with a platinum (Pt) reference electrode on a single chip (1.2 cm×1.2 cm) was developed as disclosed in the methods herein. The chip is segregated in four different sets of devices and Polydimethylsiloxane (PDMS) wells were mounted to functionalize the chip with four different probes for multianalyte detection of opioid metabolites as shown in FIGS. 2 and 8. To further ensure the accuracy and robustness of the sensor, five G-FET devices were developed in each well to average the output signal and calculate the standard deviation. Furthermore, the external Pt reference electrode was eliminated by fabricating on chip side gate electrodes. To ensure the robustness of the G-FETs in wastewater devices were passivated with an aluminum oxide (AlOx) layer, exposing only the active area of graphene for selected attachment of probes. To keep the graphene surface pristine, a reliable device design and fabrication protocols were developed that ensure excellent stability and reproducibility. The devices were made in a cleanroom in a glovebox, significantly reducing the cost of production and fabrication time as well as limiting the exposure of the graphene to atmospheric contaminants as disclosed in Gray, et al., “A Cleanroom in a Glovebox.” Review of Scientific Instruments, 91 (7) (2020), the disclosure of which is incorporated by reference herein in its entirety.

The design and fabrication enhancements enable the developed AptG-FET platform to simultaneously detect four different drug metabolites from a single sample of wastewater. The aptamer's binding affinity was validated with the respective drug metabolites in standard buffer and wastewater using plasmonic and electrochemical detection techniques. Then, one of the aptamers was functionalized over the G-FET sensor to confirm the sensitivity, selectivity, and detection limit. Finally, the multianalyte detection of all three targeted metabolites were performed on the same chip and their sensitivity, affinity, and selectivity were tested.

### Example 2—Detection of NX with G-FET in 1×PBS

The G-FET sensing platform of the present disclosure was evaluated. There are two different ways to operate a G-FET to perform biosensing; one is back gate and another through an ionic liquid. Traditional back-gated G-FETs offer reference electrode free devices but require substantial voltages (>60V) with special electronics. Liquid gated G-FET sensors significantly lower the required voltage (below 2 V) as well as keep the probes and analytes in their original size and conformation. Prior work shows liquid gating is a reliable approach with less complex electronics required for back gated FET.

The G-FET platform of the present disclosure having on-chip coplanar Pt side gate electrodes was utilized, which provides a miniaturized G-FET platform and allows upscaling of the number of devices on the same chip while measuring them simultaneously. To achieve selective functionalization in the channel region, a graphene sensing window of 10 μm×40 μm was defined by depositing and selectively etching 50 nm of AlOx. This thickness of AlOx around the contact pads further improves the stability of the sensor by passivating the source/drain electrodes and minimizing leakage current.

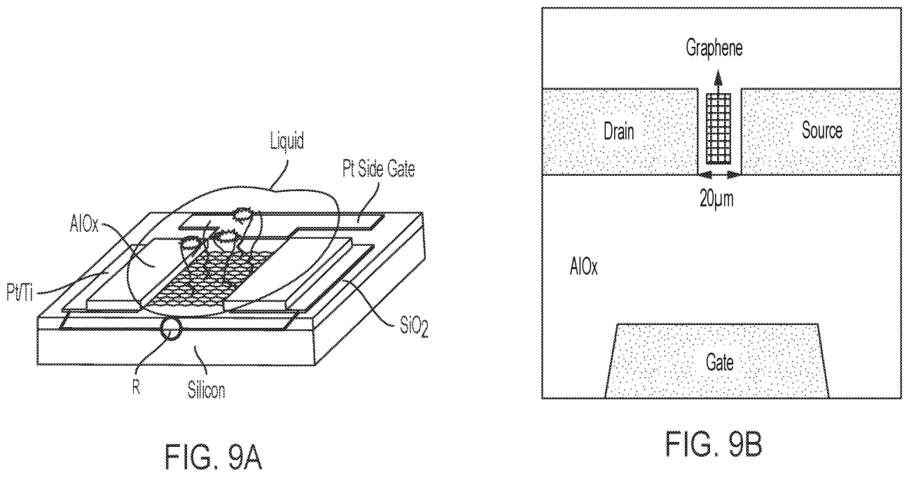

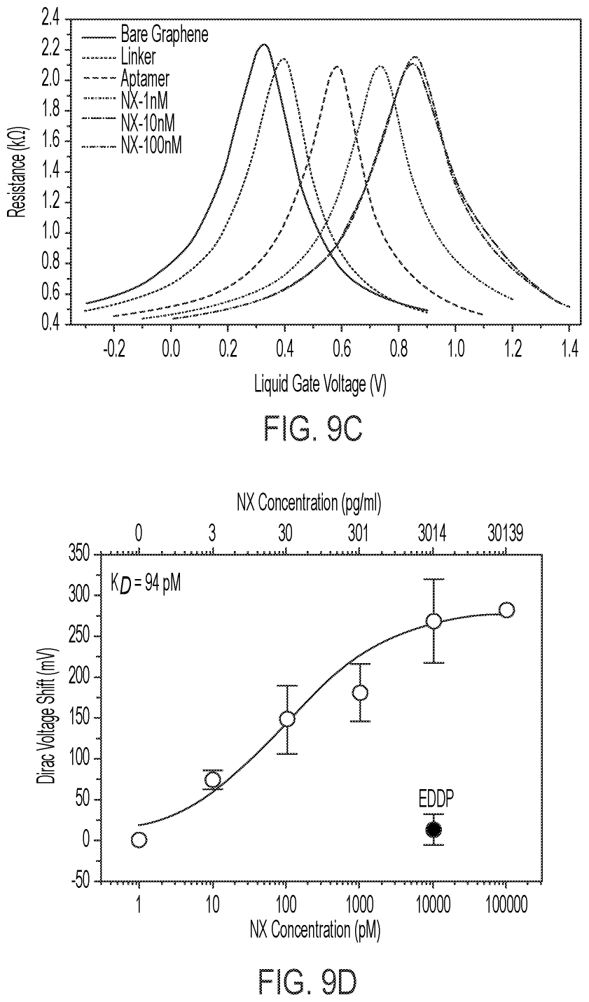

For the specific detection of the NX target, the G-FETs were first functionalized with 1 mM 1-pyrenebutyric acid N-hydroxysuccinimide ester (PBASE) linker dissolved in dimethylformamide (DMF) for 1 h and rinsed with DMF, isopropyl alcohol (IPA), and DI water. Then, NX-aptamer with 10 μM concentration was incubated for 1 h and rinsed with PBS, and DI water. Raman spectroscopy confirmed the attachment of aptamers to graphene. To obtain a resistance vs liquid gate voltage plot, the measurements were performed in 0.01×PBS to minimize the Debye screening effect. FIG. 9C shows the shift in Dirac voltage (VD) after successive functionalization with PBASE linker and NX-aptamers. Further shift in VD was observed upon incubation of NX target at concentrations of 1 nM and 10 nM while saturating when measured with 100 nM. Several devices have been tested to obtain the concentration dependent shift in VD as shown in FIG. 9D. No significant shift was observed at 1 pM while an incremental shift was recorded at 10 pM and higher values of NX concentration.

To understand the binding kinetics of the aptamers with NX, the calibration curve was fit to Hill's equation:

$$V\_D = ( V\_D \hat{} max * C \hat{} n ) / ( K\_D \hat{} n + C \hat{} n ) \qquad ( 1 )$$

Here V_D is the measured Dirac voltage shift at different concentrations of NX, V_D\hat{ }max is the Dirac voltage shift when all the binding sites are saturated, C is the concentration of NX, KD is the dissociation constant, and n is the Hill's coefficient. As shown in FIG. 9D, the resulting fit provides an excellent description of the concentration dependence. Interestingly, KD of 94 pM was found, which is much better than the conventional fluorescent and HPLC techniques yet comparable to G-FET based biosensors used for other types of biomarkers. LOD was calculated using the 3-Sigma rule (3σ/slope) where a is the standard deviation of controls while slope is obtained by linearly fitting the calibration curve. The obtained LOD from the calibration curve was approximately 10 pM which is nearly two orders of magnitude higher than that obtained with fluorescent assay and mass spectrometry and is comparable to that obtained for oxycodone utilizing electrodes modified with different complex nanostructures and immobilization process. To confirm the specificity, the NX-aptamers functionalized G-FET were tested with 100 nM EDDP, only a small shift of 8 mV was seen which is much lower than that (˜60 mV) obtained with 10 pM of NX concentration (FIG. 9D). This confirmed that aptamers used for NX detection are also highly specific.

### Example 3—Multianalyte Detection of Three Different Targets in Wastewater

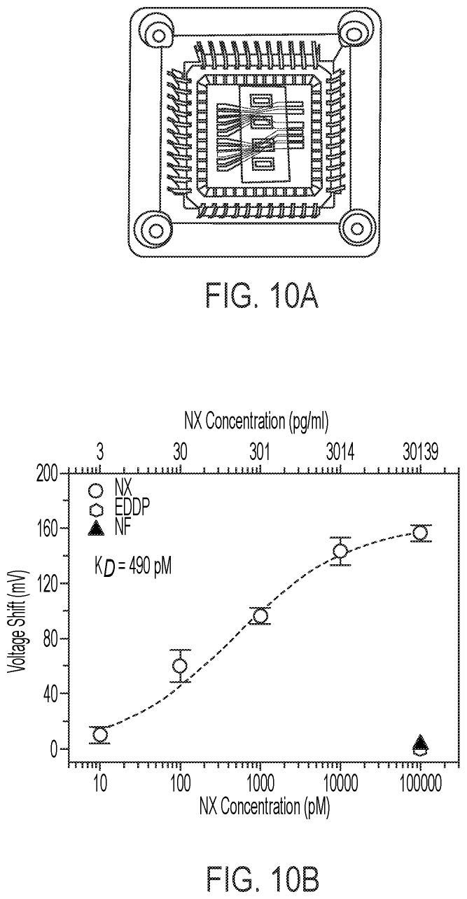

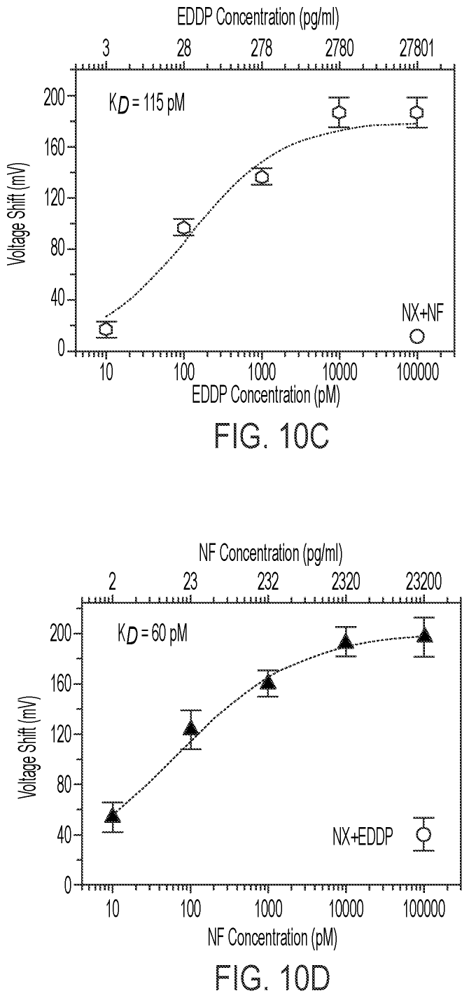

After confirming the sensitivity and specificity of the NX-aptamer in 1×PBS, the three different opioid metabolites (NX, EDDP, and NF) were tested together in real wastewater samples. To test them all together, the G-FET detection platform of the present disclosure was utilized. The entire platform is 5 cm×8 cm including the G-FET chip with four wells enabling ease of use and portability (FIG. 10A). Since a digital multimeter is only required for measuring resistance (0-5 kΩ) and a voltage supply (0-2V), the electronics can be easily miniaturized for future point of need diagnostics. Each PDMS well can hold 10 μL of solution.

The devices in all the wells are measured simultaneously before and after functionalization. Three different wells were first functionalized with PBASE linker followed by three different aptamers, i.e. NX-Apt, EDDP-Apt, and NF-Apt while the fourth well is used as a control. In this way, each well has an aptamer for one respective target. The as fabricated G-FETs were tested with raw wastewater which resulted in minimal variation in characteristics (i.e.—V_{D}, mobility, resistance) confirming the stability of the devices. However, no shift in V_{D} was observed until 1 M of NX target because of the interference caused by several other analytes and species. So, filtered and diluted (20× in binding buffer) wastewater spiked with different concentration of targets was utilized. Then, the simultaneous detection of all three targets was performed. To avoid non-specific binding at the graphene surface and minimize the interference of different analytes likely present in wastewater, both end amine-terminated polyethylene glycol (PEG 1 KDa) was mixed in a 1:1 ratio with the aptamers during functionalization.

There two different ways to attach the blocking agents. One is after the incubation of aptamers, and another is together with aptamers. The second method was chosen because it minimizes the number of functionalization steps which also minimize chances of the devices being damaged during incubation and measurement process, as well as reducing the eventual cost of the device fabrication. Another advantage is that the PEG can be uniformly distributed between the aptamers by using mixture of PEG/Ethanolamine and PEG/DNA aptamers for specific and sensitive detection of PSA in high strength buffers. The utilization of PEG mixed with aptamers resulted in more stable behavior with minimized drift and standard deviation in calculated error bars. The other two targets were utilized as negative controls while detecting the third target. For example, high concentrations (100 nM) of EDDP and NF were used as negative controls for the well functionalized with NX-Apt, then successive detection of different NX concentrations was performed (FIG. 10B). No significant shift in V_{D} was observed with EDDP and NF while an incremental voltage shift was observed with increasing NX concentration. The shift in V_{D} saturated around 100 nM suggesting most available binding sites of aptamer probes are occupied with added integration of target analyte. Similar trends of concentration dependent voltage shifts were observed with other the two targets (EDDP and NF) as shown in FIGS. 10C and 10D. Juxtaposed to NX and EDDP, the devices functionalized with NF-Apt showed a higher shift (˜50 mV) with NF target concertation at 10 pM, which could be attributed to the higher binding affinity of this aptamer (FIG. 10D). However, the devices functionalized with NF-Apt also showed a voltage shift of ˜40 mV when tested in the presence of NX and EDDP targets of concentrations (100 nM), this confirms some level of binding of other components of wastewater (FIG. 10D).

To confirm the binding kinetics of these aptamers and targets in 20× wastewater, the calibration curves obtained with all three AptG-FETs were fitted to the Hill's equation (Equation 1). The obtained ‘n’ values for all three different opioid metabolites are 0.61, 0.71, 0.53 for NX, EDDP, and NF, respectively, and agree with aptamers designed to have single binding sites. They all showed strong binding affinity as evident from the resulted KD values of 490 pM, 115 pM, and 60 pM for NX, EDDP, and NF, respectively. The higher binding affinity (KD) of aptamers and sensitivity of G-FETs resulted in significantly lower statistical LOD values of 126 pM (38 pg/ml), 96 pM (27 pg/ml), and 183 pM (42 pg/ml) for NX, EDDP, and NF respectively. Visually the LOD values look lower than those than the statically calculated values specifically for Norfentanyl as shown in FIG. 10D. This is attributed to fluctuation the control measurements which resulting in higher standard deviation. These obtained values of KD and LOD are 2 to 3 orders of magnitude lower than those reported in the literature for all three drug metabolites. Considering the 1:20 dilutions of used wastewater, these obtained LOD values are still on the order of 100 pg/ml with the detection range of pg/ml to ng/ml which is in line with the concentration range of metabolites present in wastewater.

### Example 4—Selective Detection in 20× Wastewater

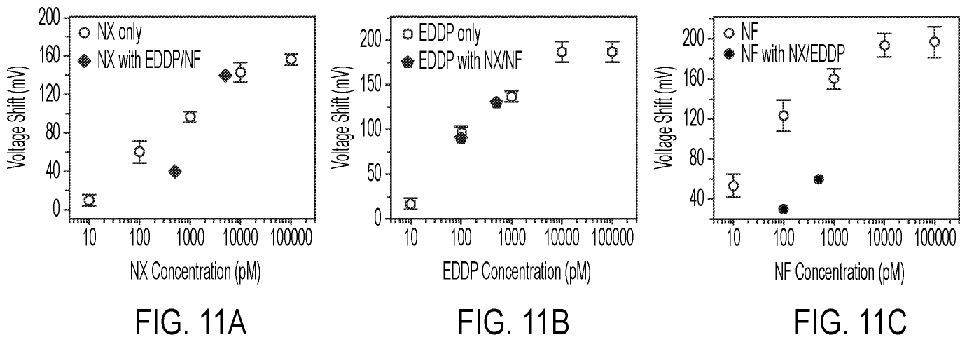

After confirming the sensitivity and specificity of the opioid metabolites in 20× wastewater, their selectivity was tested. Specifically, the one specific target was mixed with other two non-specific targets and detection was performed with G-FETs to see the hinderance in signal in comparison with that detected individually. FIG. 11A shows the signal obtained from two different concentrations of NX target mixed with similar amounts of EDDP and NF, obtained values are slightly lower than that tested with NX alone as a target. A similar test was also performed for EDDP which shows the voltage shift much closer to that obtained with a single target present (FIG. 11B). However, the voltage shift with NF when mixed with NX and EDDP was significantly lower as compared to the other two targets (FIG. 11C). This lower shift could be attributed to the interference of other targets as we have already observed some level of unspecific binding with NF-aptamers. This confirms that these AptG-FETs possess promising selectivity level along with their high sensitivity and affinity in 20× wastewater.

The capabilities of aptamer probe-based G-FET sensors for rapid, selective, and simultaneous detection of three different drug metabolites in wastewater were demonstrated. The AptG-FET platform of the present disclosure provides multianalyte detection on a single chip (1.2 cm×1.2 cm) which consists of four different PDMS wells each having five devices, on chip coplanar side gate electrodes, and passivation layer of AlOx layer. The AptG-FET platform showed high specificity, sensitivity, and selectivity for all three opioid metabolites used in this work. The achieved LOD values of 38, 27, and 42 pg/ml for NX, EDDP, and NF respectively, are well in line with the desired limits in wastewater and are 2-3 orders of magnitude better that what has been achieved with other techniques.

All AptG-FETs have shown high binding affinity with K_{D} values of 490 pM, 115 pM, and 60 pM for NX, EDDP, and NF respectively. Thus, the presented AptG-FET platform is capable to be utilized for real time monitoring of illicit drugs in wastewater and can provide a boost to the WBE. The current device design is straightforward to scale to a larger number of wells for detecting an array of analytes. Though, a lot of efforts involved in the G-FET based technology. But the presented platform can be easily upscaled to 6-inch wafer which can result in 100 chips per wafer with almost same amount of process time. Also, in future the linker can be pre-attached to whole wafer before dicing which will further eliminate the use of any chemicals while aptamers can just be used in aqueous solutions. In the future, the same platform, with different probes, could be utilized for wastewater-based monitoring of a variety of analyte types including pathogens and other disease biomarkers in local health monitoring and epidemiology studies. Furthermore, the device's design, size, rapid response, multianalyte capabilities, scalability and ease of operation enable an upcoming era of wastewater epidemiology at the local level.

### Example 5—Materials and Methods

1-pyrenebutyric acid N-hydroxysuccinimide ester (PBASE) linker and Dimethylformamide (DMF) were obtained from Sigma Aldrich. All aptamers (5′-amine-Aptamer-3′: Norfentanyl: CFA0071-GP5-25 AKA-H6AAZ; NX: CFA0079-GP5-25, AKA-H4LFD and EDDP: CFA0661-GP5-25) and their resuspension buffer were purchased from Base Pair Biotechnologies, Inc., Pearland, TX 77584 which has developed aptamers that are capable of binding noroxycodone, EDDP, and norfentanyl, and has readily available aptamers for Morphine. Target noroxycodone hydrochloride, EDDP, and norfentanyl oxalate were purchased as ampules of 1 mL with concentration 1 mg/mL in methanol (as free base) from Sigma Aldrich, St. Louis, MO 63103, USA. Disposable screen-printed carbon electrodes (SPCEs) were purchased from Metrohm (DRP-110CNT) with carbon working and auxiliary electrodes and silver as the reference electrode where the working electrodes were modified with carboxyl functionalized with multi-walled carbon nanotubes (MWCNT-COOH). Ambion™ DEPC-treated nuclease-free water (0.2 μm filtered and autoclaved) was purchased from Invitrogen, Thermo Fisher Scientific (Waltham, MA, USA) and utilized in all studies. To avoid any DNase contamination, DNA Away (DNA Surface Decontaminant) was purchased from Thermo Scientific and used before performing any experiment. All other reagents and buffers were purchased from Sigma-Aldrich, St. Louis, MO 63103, USA. The influent (raw and untreated) wastewater samples were collected from The Massachusetts Alternative Septic System Test Center (MASSTC), located in Sandwich, MA. To avoid interference in detection due to the presence of the bigger objects and species, the as received wastewater sample was treated by the following process: initial filtering by a 0.22-micron filter, 14 followed by further dilution to 1:20 in binding buffer solution (1×PBS+2 mM MgCl2+1% Methanol) and spiked with different concentrations of opioid metabolites. The dilution step we employed to ensure proper binding with the aptamers. In all reported LOD, the dilution has already been accounted for, such that the levels are those that would be present in the original sample.

### Example 6—G-FET Fabrication, Characterization, and Functionalization

G-FETs were fabricated with chemical vapor deposition (CVD) monolayer graphene transferred over SiO₂/Si substrates. Monolayer graphene was grown on copper via low pressure chemical vapor deposition. The copper foil (Alfa Aesar) was pre-treated in Ni etchant (Transene) to remove any coatings or oxide layers from its surface. The tube furnace was evacuated to a read pressure of 200 mTorr with a constant flow of H2 (10 sccm). Prior to growth, the foil was annealed at 1010° C. (ramp rate 25° C./min) for 35 minutes. Growth was done at 1010° C. with 68 sccm of H2 and 3.5 sccm of CH4 for 15 minutes. After growth, a polymethyl methacrylate (PMMA) layer was spin coated on one side of the copper foil and baked for 60 seconds at 60° C. To facilitate smooth and fast etching of the copper foil, the backside graphene was etched using oxygen plasma with 60 Watt power for 60 seconds. The exposed copper was etched away in Nickel etchant for 2 h at 60° C.

The remaining PMMA/graphene structure was washed in three DI water baths, the first and second water baths for 60 seconds each and the third for 30 minutes, to rinse away left-over etchant. To fabricate the presented G-FET platform, the source/drain along with coplanar gate electrodes were patterned on SiO₂/Si chips of size 1.2 cm×1.2 cm using bilayer photoresist (LOR1A/S1805) and laser mask writer (Heidelberg Instruments) followed by Pt/Ti (20 nm/5 nm) deposition with e-beam (Angstrom Engineering) and lift off using remover PG (MicroChem). To remove photoresist residues and improve the adhesion of electrodes, a 10 h baking was performed at 400 degrees Celsius in vacuum which resulted in clean and smoother electrodes.

The PMMA/graphene was then transferred onto these prepatterned Pt/Ti electrodes. Any leftover water was slowly dried with argon gas, and finally the PMMA was dissolved in acetone vapors; IPA (Fisher) was used for a final wash. The chips were baked at 300 degrees Celsius for 8 h in vacuum to ensure graphene adhesion and further clean photoresist residue. This was followed by deposition of 3 nm AlOx at room temperature by e-beam deposition to protect the graphene. Substrates were baked at 175 degrees Celsius for 10 minutes before lithography process.

After that the graphene patterning was done with lithography using same bilayer resists and then etched with oxygen plasma for 30 s at 75 Watt followed by 3 minutes of Argon plasma at 100 Watt to remove any oxide formed over Pt gate electrodes. Devices were cleaned with remover PG and rinsed with IPA, DI water and dried with Argon followed by removal of the 3 nm AlOx layer by dipping in MF-321 developer for 30 seconds. Then, for electrode passivation to protect the electrodes and edges of the graphene for liquid gating, 50 nm AlOx was deposited using e-beam and AlOx crystals (Lesker) at oxygen pressure of 7.5×105 mbar. Photolithography was done using S1805 to expose the sensing area (10×40 μm), gate electrodes, and contact pads while leaving remaining chip covered. The chips were post baked at 120 degrees Celsius for 5 minutes followed by AlOx etching in transetch (Transene) for 7:30 minutes at 80 degrees Celsius hot plate temperature. To hold the solution for experimental measurements and for functionalization, PDMS wells of size 1.5×1.2 mm were fabricated and placed over the chip segregating the four sets of devices with five devices in each well.

### Example 7—G-FET Functionalization and Measurements

Fabricated G-FETs were functionalized with respective aptamers for specific and selective detection of opioids. G-FET chips were incubated for an optimized time of 1 h with high concentration (10 mM) PBASE linker dissolved in DMF. Next, the G-FET was rinsed with DMF to remove adsorbed linker molecules followed by rinsing with IPA, DI to clean the surface of solvents. The pyrene group in PBASE linker stacks over the graphene surface through 71-71 interaction while the N-hydroxysuccinimide (NHS) ester reacts with amine terminated at 5′ end of aptamers 23. Chips functionalized with linker were incubated for 1 h with an optimized aptamers' concentration of 10 μM in PBS solution with 2 mM MgCl2. This concentration provided the maximized surface coverage of the exposed graphene surface of the sensor which helps to achieve high specificity and lower LOD.

Finally, the chips were rinsed with PBS to remove excess aptamers, followed by DI to clean the salts from the graphene surface. For target detection, different incubation times were tested to maximize the binding and 40 minutes was optimum to obtain the consistent signal at 10 pM concentration and same is used for all other concentrations.

### Example 8—Influenza Testing

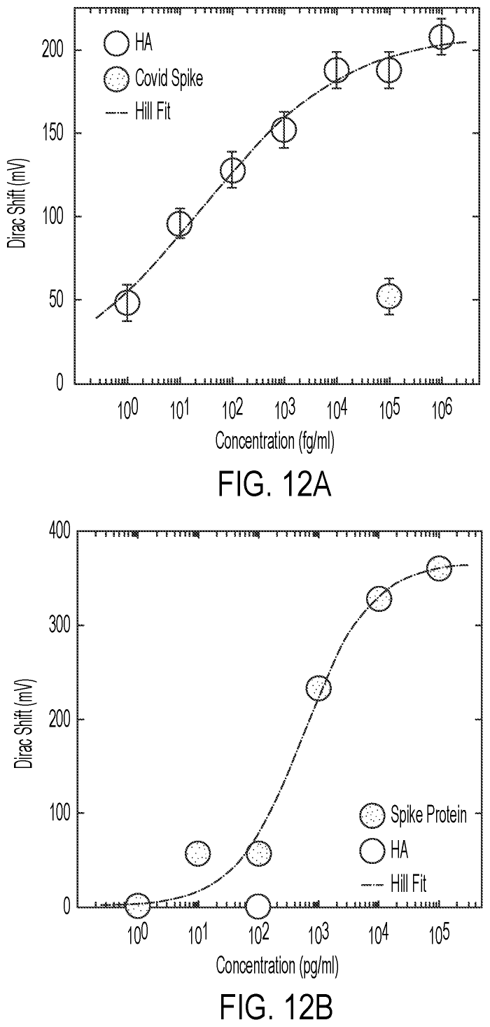

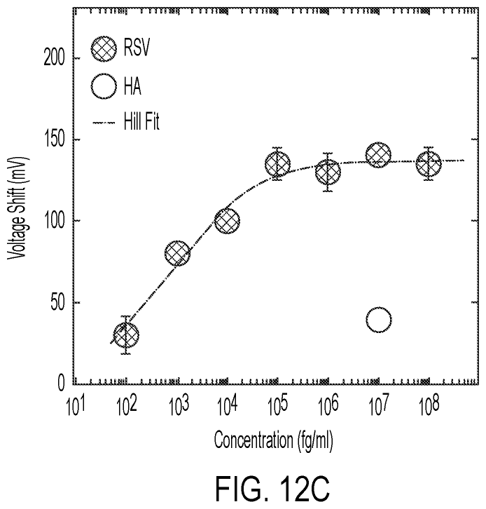

FIGS. 12A-12C illustrate test results using the multianalyte detection device of the present disclosure to detect the spike protein, HA protein (from influenza A), and the protein on the surface of the Respiratory syncytial viruses (RSV). The results were obtained in buffer and show 1-2 orders of magnitude improved limit detection compared to rapid tests.

Although various embodiments have been depicted and described in detail herein, it will be apparent to those skilled in the relevant art that various modifications, additions, substitutions, and the like can be made without departing from the spirit of the disclosure and these are therefore considered to be within the scope of the disclosure as defined in the claims which follow.

What is claimed is:

1. A method for fabricating a multianalyte detection device, the method comprising:
transferring a graphene layer onto a substrate having sources, drains, and side gates for a plurality of graphene field effect transistor devices located thereon;
baking the graphene layer to improve attachment and clean a surface of the graphene layer;
depositing a first passivation layer on the graphene layer to protect the graphene layer;
patterning a second photoresist provided on the first passivation layer to expose first portions of the graphene layer to be removed from the substrate and to provide second portions of the graphene layer covered by the first passivation layer and the second photoresist layer;
etching the graphene layer to remove the first portions of the graphene layer, wherein the second portions of the graphene layer form a plurality of graphene active regions between the source and the drain electrode of each of the plurality of graphene field effect transistors for detection of an analyte therein;
cleaning the side gates for the plurality of graphene field effect transistor devices;
depositing a second passivation layer on the substrate;
patterning a third photoresist layer provided on the second passivation layer to expose portions of the first passivation layer and the second passivation layer; and
etching the portions of the first and second passivation layers to expose graphene windows for the graphene active regions of the graphene layer configured to receive a liquid for detection of the analyte therein, contact pads, and the plurality of graphene field effect transistor devices to form the multianalyte detection device.

2. The method of claim 1, wherein the patterning steps are performed using lithography.

3. The method of claim 1, wherein the deposited metal comprises one or more of platinum and titanium.

4. The method of claim 1, wherein the first and second passivation layers are formed of aluminum oxide.

5. The method of claim 4, wherein the first and second passivation layers each have a thickness of at least 50 nanometers.

6. The method of claim 1, wherein the substrate has dimensions of about 1.2 cm by 1.2 cm.

7. The method of claim 1, wherein the side gates are coplanar to the plurality of the graphene field effect transistor devices on the substrate.

8. The method of claim 1, wherein the graphene windows have dimensions of about 10 μm×40 μm.

9. The method of claim 1, wherein the multianalyte device is configured to provide multiplexed detection of one or more chemicals or bio-analytes.

10. The method of claim 1, wherein the baking is at a temperature of at least about 300 degrees Celsius.

11. The method of claim 10, wherein the baking is for at least about 9 hours.

12. The method of claim 1, wherein the graphene layer is etched using oxygen plasma.

13. The method of claim 12, wherein the side gates for the plurality of graphene field effect transistor devices are cleaned using argon plasma.

14. The method of claim 13, wherein the cleaning the side gates for the plurality of graphene field effect transistor devices using argon plasma removes platinum oxide formed on the side gates from the etching using oxygen plasma.

15. The method of claim 1 further comprising:
wiring the multianalyte detection device to one or more polydimethylsiloxane (PDMS) wells.

16. A multianalyte detection device comprising:
a substrate having a plurality of graphene field effect transistor devices each having a source, a drain, and a side gate located thereon;
a plurality of graphene windows located on the substrate between the source electrode and the drain electrode of each of the plurality of graphene field effect transistors for receiving a liquid for detection of an analyte therein;
one or more passivation layers positioned on the substrate to protect the source electrode and the drain electrode for each of the plurality of graphene field effect transistor devices from the liquid received in the plurality of graphene windows.

17. The multianalyte detection device of claim 16, wherein the substrate has dimensions of about 1.2 cm by 1.2 cm.

18. The multianalyte detection device of claim 16, wherein the one or more passivation layers are formed of aluminum oxide.

19. The multianalyte detection device of claim 18, wherein the one or more passivation layers have a thickness of at least 50 nanometers.

20. The multianalyte detection device of claim 16, wherein the plurality of graphene field effect transistor devices comprises at least twenty graphene field effect transistor devices.

21. The multianalyte detection device of claim 16, wherein the side gates are coplanar to the plurality of the graphene field effect transistor devices on the substrate.

22. The multianalyte detection device of claim 21, wherein the side gates are formed from platinum.

23. The multianalyte detection device of claim 16, wherein the plurality of graphene field effect transistor devices are formed from platinum and titanium.

24. The multianalyte detection device of claim 16, wherein the graphene windows have dimensions of about 10 μm×40 μm.

25. The multianalyte detection device of claim 16 further comprising:
a plurality of polydimethylsiloxane (PDMS) wells coupled to the graphene layer.

26. The multianalyte detection device of claim 16, wherein the multianalyte device is configured to provide multiplexed detection of one or more chemicals or bio-analytes.
